(19) United States
(12) Patent Application Publication
(10) Pub. No.: US 2025/0272849 A1
(43) Pub. Date: Aug. 28, 2025

(54) METHOD FOR DETECTING IMAGE BOUNDARY USING GAN MODEL, COMPUTER READABLE RECORDING MEDIA, AND ELECTRONIC APPARATUS

(71) Applicant: Winbond Electronics Corp., Taichung City (TW)

(72) Inventors: Tung-Yu Wu, Taichung City (TW); Tsung-Wei Lin, Taichung City (TW); Chun-Sheng Wu, Taichung City (TW)

(73) Assignee: Winbond Electronics Corp., Taichung City (TW)

(21) Appl. No.: 19/017,788

(22) Filed: Jan. 13, 2025

(30) Foreign Application Priority Data
Feb. 23, 2024 (TW) 113106637

(51) Int. Cl. G06T 7/13

(52) U.S. Cl. CPC G06T 7/13; G06T 2207/20081; G06T 2207/20084

(57) ABSTRACT

A method for detecting an image boundary using a generative adversarial network (GAN) model is provided. The GAN model includes a generator network and a discriminator network. The method includes the following steps. The GAN model is trained using a plurality of image pictures to obtain a weight value, an average value of a generator network loss parameter, and an average value of a discriminator network loss parameter. A generator network is updated with a first loss parameter, wherein the first loss parameter is a weighted sum of the average value of the generator network loss parameter and the average value of the discriminator network loss parameter. The discriminator network is updated with a second loss parameter, wherein the second loss parameter is the average value of the discriminator network loss parameter.

### CROSS-REFERENCE TO RELATED APPLICATION

This application claims the priority benefit of Taiwan application serial no. 113106637, filed on Feb. 23, 2024. The entirety of the above-mentioned patent application is hereby incorporated by reference herein and made a part of this specification.

### BACKGROUND

### Technical Field

The disclosure relates to a method for detecting an image boundary, a computer readable recording media, and an electronic apparatus, and in particular to a method for detecting an image boundary using a generative adversarial network model, a computer readable recording media, and an electronic apparatus.

### Description of Related Art

A transmission electron microscope (TEM) may be used to take microscopic images of semiconductor elements to measure grain boundaries therein. However, when a TEM is used to take images of semiconductor elements, the grain boundaries of the images often need to be measured by the subjective judgment of the user. The boundary interfaces in the obtained image pictures may easily be unclear, have a lot of noise, and be challenging to remove. In addition, the boundary analysis cannot be performed using the scanning electron microscope (SEM) algorithm.

### SUMMARY

The disclosure provides a method for detecting an image boundary using a generative adversarial network model, a computer readable recording media, and an electronic apparatus for quickly obtaining an accurate image boundary result.

Regarding a method for detecting an image boundary using a generative adversarial network (GAN) model in an embodiment of the disclosure, the GAN model includes a generator network and a discriminator network. The method includes the following steps. The GAN model is trained with a plurality of image pictures to obtain a weight value, an average value of a generator network loss parameter, and an average value of a discriminator network loss parameter. The generator network is updated with a first loss parameter. The first loss parameter is a weighted sum of the average value of the generator network loss parameter and the average value of the discriminator network loss parameter. The discriminator network is updated with a second loss parameter. The second loss parameter is the average value of the discriminator network loss parameter.

A computer readable recording media in an embodiment of the disclosure includes a computer program. The computer program enables a computer to perform the method for detecting the image boundary using the GAN model after executing the computer program.

An electronic apparatus in an embodiment of the disclosure includes a processor and a storage element. The storage element stores a computer program. The computer program enables the processor to perform the method for detecting the image boundary using the GAN model after executing the computer program.

To make the aforementioned more comprehensible, several embodiments accompanied with drawings are described in detail as follows.

### BRIEF DESCRIPTION OF THE DRAWINGS

FIG. 1 illustrates a block schematic diagram of an electronic apparatus in an embodiment of the disclosure.

FIG. 2 illustrates a flowchart of steps of a method for detecting an image boundary using a GAN model in an embodiment of the disclosure.

FIG. 3 illustrates an outline schematic diagram of the GAN model in an embodiment of the disclosure.

FIG. 4 illustrates an outline schematic diagram of a picture to be detected and a detection result thereof in an embodiment of the disclosure.

FIG. 5 illustrates an outline schematic diagram of a sliced original image and a sliced true image in the embodiment in FIG. 3.

FIG. 6 illustrates an outline schematic diagram of a picture slicing method in an embodiment of the disclosure.

FIG. 7 illustrates a training flowchart of a GAN model in an embodiment of the disclosure.

FIG. 8 illustrates an outline schematic diagram of a lookup table for determining a weight value in an embodiment of the disclosure.

FIG. 9 illustrates a schematic flowchart of a boundary enhancing operation in an embodiment of the disclosure.

FIG. 10 illustrates a schematic flowchart of a boundary defining operation in an embodiment of the disclosure.

### DESCRIPTION OF THE EMBODIMENTS

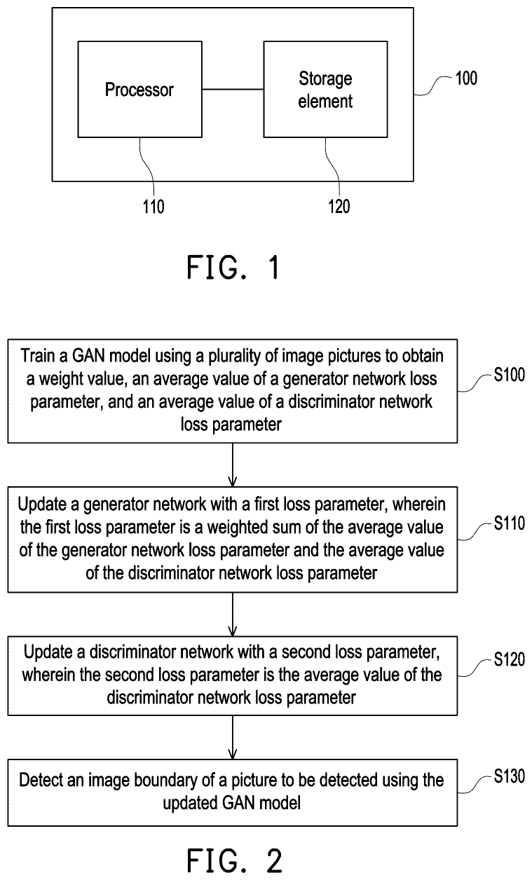

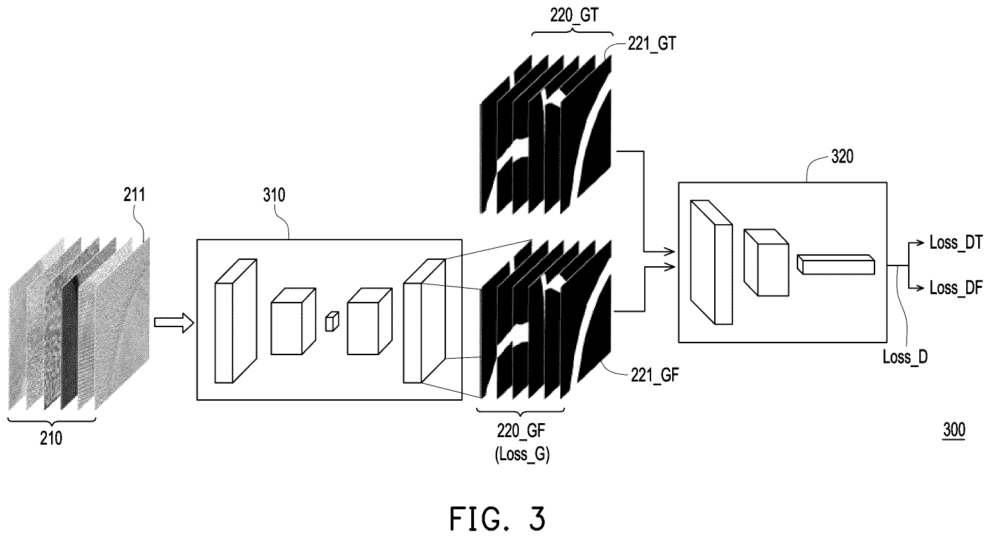

Referring to FIGS. 1 to 4, an electronic apparatus 100 includes a processor 110 and a storage element 120. In an embodiment, the electronic apparatus 100 is, for example, a computer, and the storage element 120 is, for example, a computer readable recording media, including a computer program. The electronic apparatus 100 may execute a method for detecting an image boundary using a generative adversarial network (GAN) model in FIG. 2 after executing the computer program. A GAN model 300 in FIG. 3 includes a generator network 310 and a discriminator network 320.

In step S100, the processor 110 trains the GAN model 300 using a plurality of image pictures 210, 220_GF, and 220_GT to obtain a weight value, an average value of a generator network loss parameter Loss_G, and an average value of a discriminator network loss parameter Loss_D. In step S110, the processor 110 updates the generator network 310 with a first loss parameter. For example, the processor 110 may update a variable that needs to be updated in the generator network 310. The first loss parameter includes a weighted sum of the average value of the generator network loss parameter Loss_G and the average value of the discriminator network loss parameter Loss_D. In step S120, the processor 110 updates the discriminator network 320 with a second loss parameter. For example, the processor 110 may update a variable that needs to be updated in the discriminator network 320. The second loss parameter includes the average value of the discriminator network loss parameter Loss_D. In step S130, the processor 110 detects an image boundary of a picture to be detected 410 using the updated GAN model.

The method for detecting the image boundary in FIG. 2 is suitable for analyzing various image pictures to quickly obtain an accurate image boundary detection result. For example, the method for detecting the image boundary in FIG. 2 may be used to analyze a transmission electron microscope (TEM) image to quickly obtain a highly accurate detection result of a TEM image boundary. The picture to be detected 410 in FIG. 4 is, for example, the TEM image, and the TEM image may include a floating gate layer image and an active area layer image of a memory element. In a detection result 420 in FIG. 4, image boundaries 422 and 424 are, for example, grain boundaries in the TEM image.

In an embodiment, the processor 110 is, for example, a central processing unit (CPU), other programmable general-purpose or specific-purpose micro control units (MCU), microprocessors, digital signal processors (DSP), programmable controllers, application specific integrated circuits (ASIC), a graphics processing units (GPU), image signal processors (ISP), image processing units (IPU), arithmetic logic units (ALU), complex programmable logic devices (CPLD), and field programmable gate arrays (FPGA), other similar elements, or a combination of the above-mentioned elements.

In an embodiment, the storage element 120 is used to store various software, data, and program codes required when the electronic apparatus 100 operates. The storage element 120 is, for example, any type of fixed or removable random access memory (RAM), read-only memory (ROM), flash memory, hard disk drive (HDD), and solid state drive (SSD), other similar elements, or a combination of the above-mentioned elements. The storage element 120 may be used to store a plurality of modules or various applications that can be executed by the processor 110. In an embodiment, the storage element 120 may further include a database.

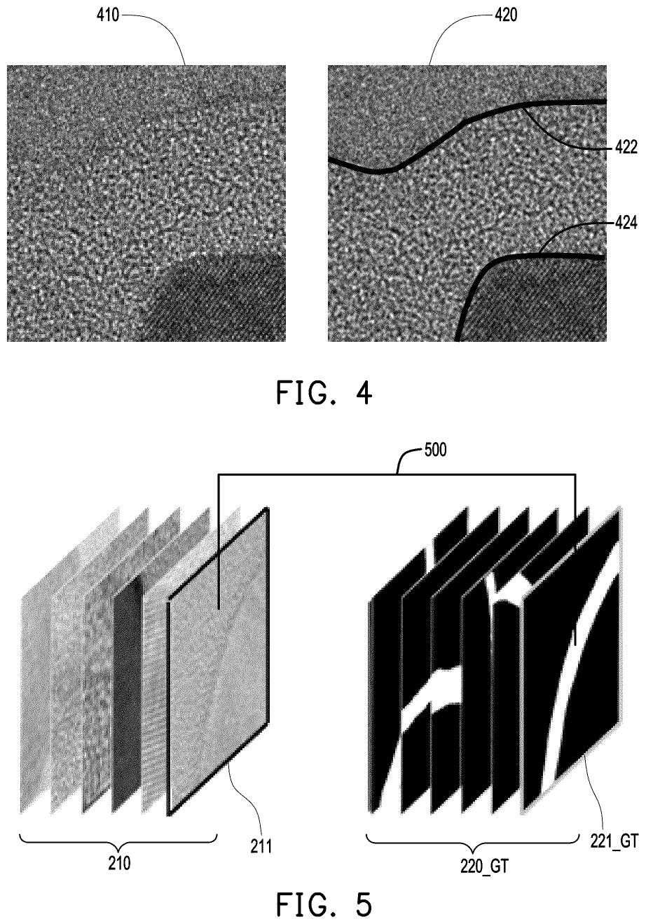

Next, a sliced image picture input into the generator network 310 and the discriminator network 320 in FIG. 3 is described. Referring to FIGS. 3 and 5, an image picture input into each network includes a sliced original image 210 and a sliced true image 220_GT. The sliced original image 210 is used to be input into the generator network 310, and the sliced true image 220_GT is used to be input into the discriminator network 320. The sliced original image 210 and the sliced true image 220_GT have a corresponding positional relationship as shown in FIG. 5, and the sliced true image 220_GT is the sliced original image 210 added with a mark by a user. For example, a sliced true image 221_GT is a sliced original image 211 added with a mark by the user, and the sliced true image 221_GT and the sliced original image 211 have a corresponding positional relationship 500. Since the sliced original image 211 and the sliced true image 221_GT have the corresponding positional relationship, the sliced original image 211 and the sliced true image 221_GT cannot be paired up arbitrarily. A set of sliced images includes the sliced true image 221_GT and the sliced original image 211 having the corresponding positional relationship. Further, data marked by the user includes 100 to 300 (e.g., 200) true image pictures, for example. Next, the 200 true image pictures are divided such that 55% to 45% (e.g., 50%) of which are used for training, 35% to 25% (e.g., 30%) are used for verification, 20% to 10% (e.g., 15%) are used for testing, and 10% to 1% (e.g., 5%) are used for weight adjustment. For a true image picture used for weight adjustment, the user re-confirms whether a marking position of the true image picture is correct. Thus, the true image picture used for weight adjustment is a picture with a higher accuracy. The disclosure is not limited to the above-mentioned values and ranges of values.

The above-mentioned true image pictures used for training, verification, testing, and weight adjustment are input into each network after being sliced. For example, the true image pictures used for training account for 50% of all true image pictures, and these 50% of all true image pictures are input into the discriminator network 320 after being sliced into sliced true images. The true image pictures that are used for training and sliced are referred to as training sliced images. In addition, by analogy, the true image pictures used for verification, testing, and weight adjustment are respectively referred to as verifying sliced images, testing sliced images, and adjusting sliced images after being sliced. Thus, the sliced true image 220_GT includes a plurality of training sliced images, a plurality of verifying sliced images, a plurality of testing sliced images, and a plurality of adjusting sliced images. Quantities of the plurality of training sliced images, the plurality of verifying sliced images, the plurality of testing sliced images, and the plurality of adjusting sliced images are sequentially the plurality of training sliced images, the plurality of verifying sliced images, the plurality of testing sliced images, and the plurality of adjusting sliced images in descending order. Thus, in an embodiment, only 50% of the training sliced images, 30% of the verifying sliced images, 15% of the testing sliced images, and 5% of the adjusting sliced images need to be used to train the GAN model.

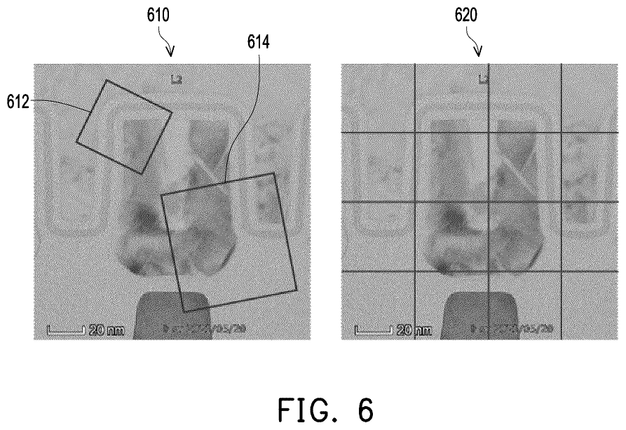

Referring to FIG. 6, a picture slicing manner in this embodiment includes a random slicing manner 610 (a first manner) and a regular slicing manner 620 (a second manner). The training sliced images and the verifying sliced images are sliced using the random slicing manner 610, and the testing sliced images and the adjusting sliced images are sliced using the regular slicing manner 620. In the random slicing manner 610, slicing parameters such as position, angle, a size, length and width, chromaticity, brightness, and contrast of sliced images 612 and 614 may be set randomly. In the regular slicing manner 620, a quantity of sliced images may be set according to design requirements.

In this embodiment, to make the trained generator network 310 and the trained discriminator network 320 learn more completely, diversity of training sliced images and verifying sliced images may be increased. Consequently, more sliced true images of different types may be created by random slicing for training, thereby improving the model strengths of the generator network 310 and the discriminator network 320. On the other hand, testing and weight adjustment require a higher accuracy as testing is to judge whether the trained GAN model 300 is reliable, and weight adjustment is to judge a weight ratio of the loss parameter from an unbiased third-party position. Neither testing nor weight adjustment can be distorted due to changing the model by random slicing or a change in position, angle, size, length and width, etc. Thus, in order to ensure that a judgment standard meets an expectation, regular slicing is used when producing the testing sliced image and the adjusting sliced image.

Next, definitions of the generator network loss parameter Loss_G and the discriminator network loss parameter Loss_D of the GAN model 300 in FIG. 3 are described.

The processor 110 inputs the sliced original image 210 into the generator network 310, and the generator network 310 receives the sliced original image 210 to generate a sliced fake image 220_GF. The processor 110 calculates a difference between the sliced fake image 220_GF and the sliced true image 220_GT, and the difference between the sliced fake image 220_GF and the sliced true image 220_GT is the generator network loss parameter Loss_G.

The processor 110 inputs the sliced fake image 220_GF into the discriminator network 320. Upon a receipt of the sliced fake image 220_GF by the discriminator network 320, a first value from 0 to 1 is obtained, wherein a difference between the first value and 0 is a discriminator network loss parameter Loss_DF corresponding to the sliced fake image 220_GF. The processor 110 inputs the sliced true image 220_GT into the discriminator network 320. Upon a receipt of the sliced true image 220_GT by the discriminator network 320, a second value from 0 to 1 is obtained, wherein a difference between the second value and 1 is a discriminator network loss parameter Loss_DT corresponding to the sliced true image 220_GT.

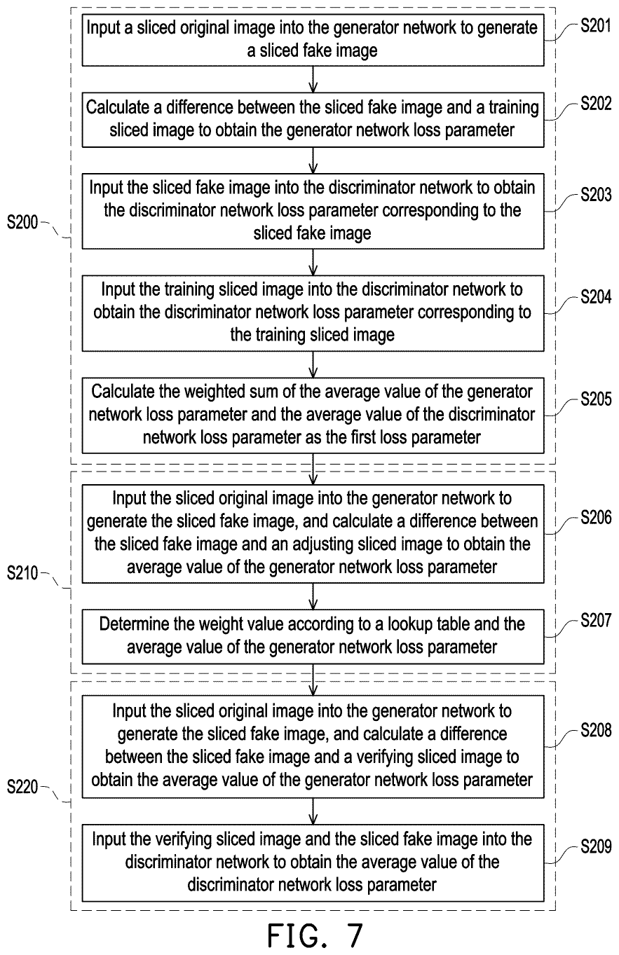

Next, a training process of the GAN model 300 in FIG. 3 is described. Referring to FIGS. 2, 3, and 7, step S100 for training in FIG. 2 includes steps S200, S210, and S220 in FIG. 7.

Specifically, in step S201, the processor 110 first inputs the sliced original image 211 into the generator network 310 to generate a sliced fake image 221_GF. Next, in step S202, the processor 110 calculates a difference between the sliced fake image 221_GF and a training sliced image of the sliced true image 220_GT. The difference between the sliced fake image 221_GF and the training sliced image of the sliced true image 220_GT is the generator network loss parameter Loss_G. A set of sliced images includes the training sliced image of the sliced true image 220_GT and the sliced original image 211 having a corresponding positional relationship. In steps S201 and S202, the average value of the generator network loss parameter Loss_G may be calculated, for example, by randomly selecting 1,000 sets of sliced images from the sliced original image 210 and the sliced true image 220_GT. The disclosure is not limited by the above-mentioned quantity of sliced images.

Next, in step S203, the processor 110 then inputs the sliced fake image 221_GF into the discriminator network 320 to obtain the first value from 0 to 1. The difference between the first value and 0 is the discriminator network loss parameter Loss_DF corresponding to the sliced fake image 221_GF. In step S204, the processor 110 also inputs the training sliced image of the sliced true image 220_GT into the discriminator network 320 to obtain the second value from 0 to 1. The difference between the second value and 1 is the discriminator network loss parameter Loss_DT corresponding to the training sliced image of the sliced true image 220_GT. The discriminator network loss parameter Loss_D includes the discriminator network loss parameters Loss_DF and Loss_DT. Thus, in step S200, the average value of the discriminator network loss parameter Loss_D may be calculated with the same 1,000 sets of sliced images.

Next, in step S205, the processor 110 calculates the weighted sum of the average value of the generator network loss parameter Loss_G and the average value of the discriminator network loss parameter Loss_D as the first loss parameter:

$$Loss\_ 1 = Loss\_MG \times W + Loss\_MD \times ( 1 - W )$$

Loss_1 is the first loss parameter, Loss_MG is the average value of the generator network loss parameter Loss_G, Loss_MD is the average value of the discriminator network loss parameter Loss_D, and W is the weight value. Thus, in step S110 in FIG. 2, the processor 110 updates a parameter in the generator network 310 with the first loss parameter Loss_1.

Additionally, a second loss parameter Loss_2 includes the average value Loss_MD of the discriminator network loss parameter Loss_D. Thus, in step S120 in FIG. 2, the processor 110 updates a parameter in the discriminator network 320 with the second loss parameter Loss_2.

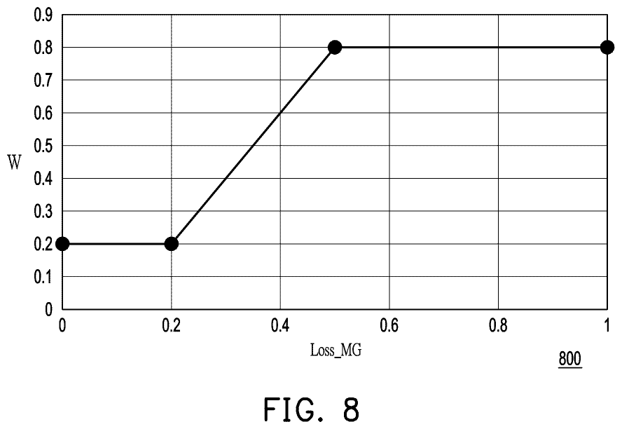

Next, an adjustment step starts from step S210. In step S206, the processor 110 inputs the sliced original image 211 into the generator network 310 to generate the sliced fake image 221_GF, and calculates a difference between the sliced fake image 221_GF and an adjusting sliced image of the sliced true image 220_GT to obtain the average value Loss_MG of the generator network loss parameter Loss_G. In step S207, the processor 110 may determine the weight value W according to a lookup table 800 in FIG. 8 and the average value Loss_MG of the generator network loss parameter Loss_G.

Next, a verification step starts from step S220. In step S208, the processor 110 inputs the sliced original image 211 into the generator network 310 to generate the sliced fake image 221_GF, and calculates a difference between the sliced fake image 221_GF and a verifying sliced image of the sliced true image 220_GT to obtain the average value Loss_MG of the generator network loss parameter Loss_G. In step S209, the processor 110 inputs the verifying sliced image of the sliced true image 220_GT and the sliced fake image 221_GF into the discriminator network 320 to obtain the average value Loss_MD of the discriminator network loss parameter Loss_D. If the average value Loss_MG of the generator network loss parameter Loss_G and the average value Loss_MD of the discriminator network loss parameter Loss_D are both less than a default threshold value, the processor 110 ends step S100 for training.

Steps S200, S210, and S220 may be referred to as a cycle, where after completing one cycle, the processor 110 first performs steps S110 and S120 to update the generator network 310 and the discriminator network 320, and then proceeds to a new cycle to train the GAN model 300.

In an embodiment, after step S100 for training ends, the processor 110 may calculate an accuracy of the GAN model 300 using a testing sliced image of the sliced true image 220_GT.

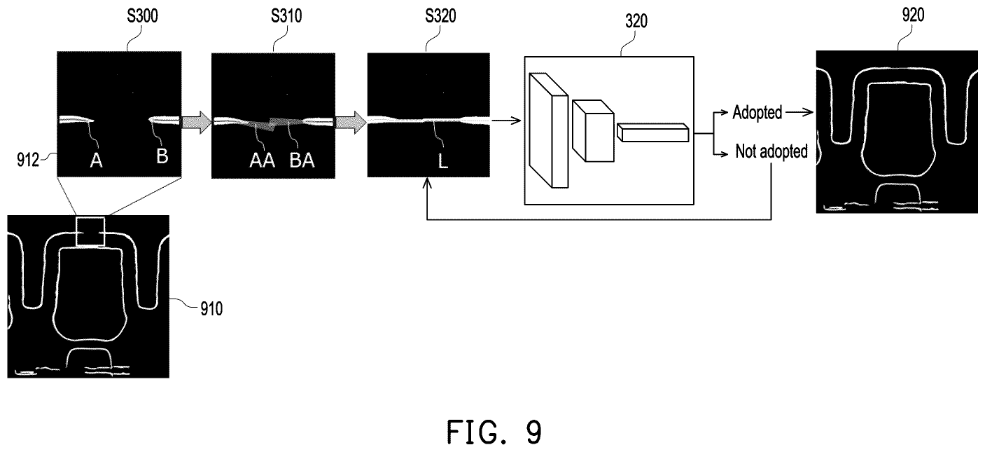

In the embodiment of the disclosure, the method for detecting a boundary may be further combined with a method for image processing to improve correctness of boundary detection, as described below. Referring to FIG. 9, a part of a boundary of a fake image picture 910 may disappear after a denoising process. For example, a sliced fake image 912 includes two disconnected bands. In this embodiment, the processor 110 may perform a boundary enhancing operation on the sliced fake image 912 through the discriminator network 320 to connect the two disconnected bands and convert the fake image picture 910 into a fake image picture 920.

Specifically, in step S300, the processor 110 identifies two end points A and B of the two disconnected bands. In step S310, the processor 110 identifies extension intervals AA and BA of the two end points A and B. In step S320, the processor 110 connects the two end points A and B at a default angle and scores a connection manner L.

If a score Y is greater than or equal to a first reference value X and is greater than or equal to a second reference value 0.95, i.e., Y=X and Y≥0.95, the connection manner L is adoptable. By the connection manner L, the processor 110 connects the two disconnected bands, thereby converting the fake image picture 910 into the fake image picture 920. On the other hand, if the score Y is greater than the first reference value X but less than the second reference value 0.95, i.e., Y>X and Y<0.95, the connection manner L is not adoptable. The processor 110 updates the first reference value X, so that X=Y. Returning to step S320, the processor adjusts the default angle to connect the two end points A and B again. In addition, if the score Y is less than the first reference value X, i.e., Y<X, the connection manner L is not adoptable. The processor 110 does not update the first reference value X. Returning to step S320, the processor 110 adjusts the default angle to connect the two end points A and B again. Thus, through the boundary enhancing operation in FIG. 9, the disconnected bands of the fake image picture may be connected, thereby improving the correctness of the subsequent boundary detection.

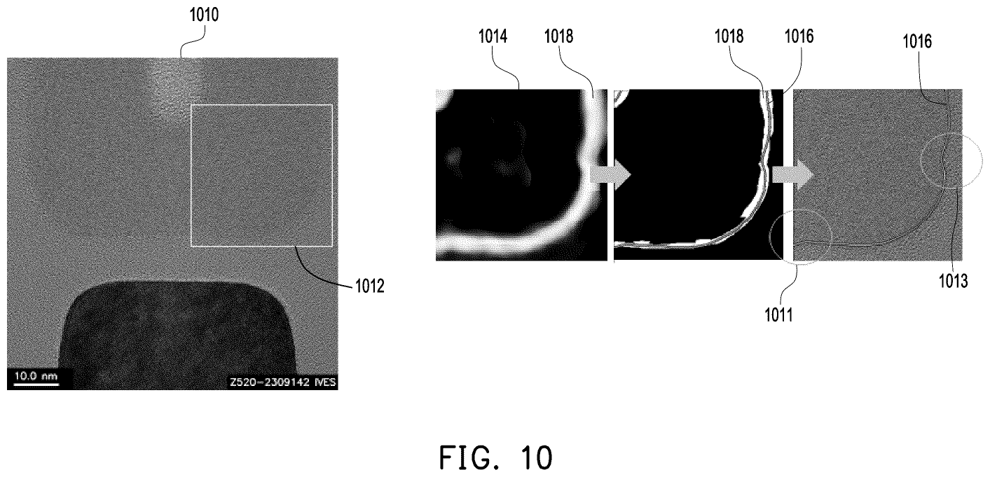

Referring to FIG. 10, the processor 110 may perform a boundary defining operation on a sliced fake image 1014 through the generator network 310 to define a boundary line 1016 therein. The sliced fake image 1014 is, for example, a sliced image corresponding to a partial region 1012 of a TEM image 1010.

Specifically, the processor 110 may define the boundary line 1016 of a band 1018 according to a brightness distribution of the band 1018. For example, each pixel in the band 1018 has a different brightness value between 0 and 1. The brighter the pixel, the higher the brightness value. Conversely, the darker the pixel, the lower the brightness value. With the brightness value as the weight value, the processor 110 may redefine a position of the boundary line 1016. Thus, more boundary details 1011 and 1013 may be retained through the boundary defining operation in FIG. 10.

In the embodiment of the disclosure, the method for detecting the image boundary using the GAN model includes an application scenario below, but is not limited thereto. In the embodiment of the disclosure, the GAN model is trained, and the trained GAN model is applied in detecting an image boundary of a semiconductor element (e.g., a memory unit). For example, after the semiconductor element is manufactured, an image of the semiconductor element may be taken through the TEM. Then, a grain boundary in the TEM image of the semiconductor element is detected through the method for detecting the image boundary in the embodiment of the disclosure to quickly obtain an accurate image boundary result. Thus, the user may adjust a manufacturing process parameter or optimize a manufacturing process of a product according to the image boundary detection result.

In summary, in the embodiments of the disclosure, the GAN model may be used to detect the boundary of the image picture automatically, and the accurate image boundary detection result is quickly obtained even if a boundary strength is not obvious. The method for detecting the image boundary in the embodiment of the disclosure uses the GAN model to define the boundary in the image picture, and dynamically adjusts the weight value of the loss parameter to reduce errors in manual marking. In addition, the method for detecting the image boundary in the embodiment of the disclosure is combined with methods for image processing such as the boundary enhancing operation and the boundary defining operation to enhance the continuity of the boundary, reduce measurement errors, and increase the accuracy of the boundary definition.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A method for detecting an image boundary using a generative adversarial network model, wherein the generative adversarial network model comprises a generator network and a discriminator network, the method comprising:
training the generative adversarial network model using a plurality of image pictures to obtain a weight value, an average value of a generator network loss parameter, and an average value of a discriminator network loss parameter;
updating the generator network with a first loss parameter, wherein the first loss parameter is a weighted sum of the average value of the generator network loss parameter and the average value of the discriminator network loss parameter;
updating the discriminator network with a second loss parameter, wherein the second loss parameter is the average value of the discriminator network loss parameter.

2. The method for detecting the image boundary using the generative adversarial network model of claim 1, wherein the plurality of image pictures comprise a sliced original image and a sliced true image, and the sliced original image and the sliced true image have a corresponding positional relationship.

3. The method for detecting the image boundary using the generative adversarial network model of claim 2, wherein the sliced true image comprises a plurality of training sliced images, and steps for training the generative adversarial network model using the plurality of image pictures comprise:
inputting the sliced original image into the generator network to generate a sliced fake image; and
calculating a difference between the sliced fake image and the plurality of training sliced images, wherein the difference between the sliced fake image and the plurality of training sliced images is the generator network loss parameter.

4. The method for detecting the image boundary using the generative adversarial network model of claim 3, wherein steps for training the generative adversarial network model using the plurality of image pictures further comprise:
inputting the sliced fake image into the discriminator network to obtain a first value from 0 to 1, wherein a difference between the first value and 0 is the discriminator network loss parameter corresponding to the sliced fake image;
inputting the plurality of training sliced images into the discriminator network to obtain a second value from 0 to 1, wherein a difference between the second value and 1 is the discriminator network loss parameter corresponding to the plurality of training sliced images; and
calculating the weighted sum of the average value of the generator network loss parameter and the average value of the discriminator network loss parameter as the first loss parameter, wherein the discriminator network loss parameter comprises the discriminator network loss parameter of the sliced fake image and the discriminator network loss parameter of the plurality of training sliced images.

5. The method for detecting the image boundary using the generative adversarial network model of claim 2, wherein the sliced true image comprises a plurality of adjusting sliced images, and steps for training the generative adversarial network model using the plurality of image pictures comprise:
inputting the sliced original image into the generator network to generate a sliced fake image, and calculating a difference between the sliced fake image and the plurality of adjusting sliced images to obtain the average value of the generator network loss parameter; and
determining the weight value according to a lookup table and the average value of the generator network loss parameter.

6. The method for detecting the image boundary using the generative adversarial network model of claim 2, wherein the sliced true image comprises a plurality of verifying sliced images, and steps for training the generative adversarial network model using the plurality of image pictures comprise:
inputting the sliced original image into the generator network to generate a sliced fake image, and calculating a difference between the sliced fake image and the plurality of verifying sliced images to obtain the average value of the generator network loss parameter; and
inputting the plurality of verifying sliced images and the sliced fake image into the discriminator network to obtain the average value of the discriminator network loss parameter,
wherein the training ends when the average value of the generator network loss parameter and the average value of the discriminator network loss parameter are both less than a threshold value.

7. The method for detecting the image boundary using the generative adversarial network model of claim 6, wherein the sliced true image comprises a plurality of testing sliced images, and step for training the generative adversarial network model using the plurality of image pictures comprises:
calculating an accuracy of the generative adversarial network model using the plurality of testing sliced images after the training ends.

8. The method for detecting the image boundary using the generative adversarial network model of claim 2, wherein the sliced true image comprises a plurality of training sliced images, a plurality of verifying sliced images, a plurality of testing sliced images, and a plurality of adjusting sliced images, with quantities sequentially being the plurality of training sliced images, the plurality of verifying sliced images, the plurality of testing sliced images, and the plurality of adjusting sliced images in a descending order.

9. The method for detecting the image boundary using the generative adversarial network model of claim 8, wherein the plurality of training sliced images and the plurality of verifying sliced images are sliced with a first manner, the plurality of testing sliced images and the plurality of adjusting sliced images are sliced with a second manner, and the first manner is different than the second manner.

10. The method for detecting the image boundary using the generative adversarial network model of claim 2, wherein the sliced true image is the sliced original image added with a mark.

11. The method for detecting the image boundary using the generative adversarial network model of claim 1, further comprising:
detecting an image boundary of a picture to be detected using the updated generative adversarial network model, wherein the picture to be detected is a transmission electron microscope image.

12. The method for detecting the image boundary using the generative adversarial network model of claim 3, further comprising:
performing a boundary defining operation for the sliced fake image through the generator network.

13. The method for detecting the image boundary using the generative adversarial network model of claim 12, wherein the sliced fake image comprises a band, and the boundary defining operation comprises:
defining a boundary line of the band according to a brightness distribution of the band.

14. The method for detecting the image boundary using the generative adversarial network model of claim 3, further comprising:
performing a boundary enhancing operation for the sliced fake image through the discriminator network.

15. The method for detecting the image boundary using the generative adversarial network model of claim 14, wherein the sliced fake image comprises two disconnected bands, and the boundary enhancing operation comprises:
identifying two end points of the two disconnected bands;
identifying extension intervals of the two end points, connecting the two end points at a default angle, and scoring a connection manner; and
when a score is greater than or equal to a first reference value and greater than or equal to a second reference value, connecting the two disconnected bands with the connection manner.

16. The method for detecting the image boundary using the generative adversarial network model of claim 15, wherein the boundary enhancing operation further comprises:
when the score is greater than the first reference value and less than the second reference value, updating the first reference value, so that the first reference value is equal to the score, returning to connecting the two end points at the default angle, scoring the connection manner, and adjusting the default angle to connect the two end points again; and
when the score is less than the first reference value, connecting the two end points at other angles without updating the first reference value, returning to connecting the two end points at the default angle, scoring the connection manner, and adjusting the default angle to connect the two end points again.

17. A computer readable recording media, comprising a computer program enabling a computer to execute the method for detecting the image boundary using the generative adversarial network model of claim 1 after executing the computer program.

18. An electronic apparatus, comprising a processor and a storage element, wherein the storage element stores a computer program enabling the processor to execute the method for detecting the image boundary using the generative adversarial network model of claim 1 after executing the computer program.
